(19) United States
(12) Patent Application Publication
(10) Pub. No.: US 2009/0301771 A1
(43) Pub. Date: Dec. 10, 2009

(54) CONDUCTIVE BUMP, METHOD FOR FORMING THE SAME, AND ELECTRONIC COMPONENT MOUNTING STRUCTURE USING THE SAME

(76) Inventors: Shozo Ochi, Osaka (JP); Kazuya Ushirokawa, Osaka (JP); Takayuki Higuchi, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/477,227

(22) Filed: Jun. 3, 2009

(30) Foreign Application Priority Data
Jun. 4, 2008 (JP) 2008-146413
Jun. 26, 2008 (JP) 2008-166798
Jun. 26, 2008 (JP) 2008-166799

(51) Int. Cl. H05K 1/16; H05K 1/11; H01R 43/02

(52) U.S. Cl. 174/260; 174/263; 29/879

(57) ABSTRACT

A conductive bump formed on an electrode of an electronic component. The conductive bump is composed of a first bump having one or more layers formed on the electrode and including resin containing at least a spherical-shaped conductive filler, and a second bump formed on an upper surface of the first bump and including photosensitive resin containing a scale-shaped conductive filler.

### BACKGROUND OF THE INVENTION

1. Field of the Invention

The present invention relates to a conductive bump formed on an electrode terminal of a semiconductor element or a connection terminal of a circuit board. More particularly, the present invention relates to a conductive bump capable of mounting narrow-pitched electrode terminals of a semiconductor element onto connection terminals of a circuit board with high connection reliability, a method for forming the conductive bump, and an electronic component mounting structure using the conductive bump.

2. Background Art

Recently, in mobile electronic devices such as portable telephones, notebook-sized personal computers and digital video cameras, technology development for realizing small-size and high-performance devices has been rapidly advanced.

One principle electronic component for supporting this technology development is a semiconductor element. In order to realize a thinner and higher-density semiconductor element, a finer wiring rule and increased pins of an electrode terminal have been remarkably developed. Accordingly, an insulating layer of a semiconductor element has been demanded to have a low dielectric constant (Low-k). Therefore, as the insulating layer, a porous layer of, for example, p-SiOC and an organic polymer, has been used. Under such circumstances, strict requirements have been made with respect to a bump used in flip-chip mounting a semiconductor element on a mount board.

Conventionally, a technology for mounting electronic components such as a semiconductor element on various circuit boards with a high density includes a flip-chip mounting technology. In usual flip-chip mounting, a metal bump having, for example, a diameter of about 150 μm and made of solder, gold, or the like, is previously formed on an electrode terminal formed on a semiconductor element such as LSI. Then, the semiconductor element is pressed and heated so as to be connected to a connection terminal of the circuit board by face-down bonding.

In particular, in order to cope with remarkably increased pins, a method called an area bump method is employed in which a bump is formed over the entire surface of a semiconductor element on which a circuit is formed. In this case, at the time of mounting, in order to cope with warp on the entire mounting area of the circuit board, a bump with a high aspect ratio is required. For example, when a next generation LSI having more than 5000 electrode terminals is mounted on a circuit board, it is necessary to form a bump corresponding to a narrow pitch of not more than 100 μm and having a high aspect ratio. However, it is difficult for current solder-bump formation technologies to meet such requirements. Therefore, in a current state, a plating method, a screen printing method, and the like, are employed as a bump formation technology. However, although the plating method is suitable for forming bumps with a narrow pitch, the bump formation step is complicated and the productivity is low. Meanwhile, although the screen printing method is excellent in productivity, use of a mask makes it difficult to form a bump satisfying a narrow pitch and a high aspect ratio.

Furthermore, in the area bump method, an insulating layer made of a fragile dielectric material or a circuit such as transistor is disposed immediately beneath an electrode terminal of a semiconductor element. Therefore, when mounting is carried out via a metal bump, with a pressurizing force at the time of press contact, a large stress is applied to the surface on which the circuit of the semiconductor element is formed and to the insulating layer. In particular, in a semiconductor element including an insulating layer made of a porous and fragile dielectric material, destruction of the insulating layer, cracking of the semiconductor element, and the like, may occur, or the property of the semiconductor element may be changed by stress.

In order to avoid the above-mentioned problems, technologies for selectively forming bumps on electrode terminals of an LSI chip or connection terminals of a circuit board have been proposed recently. These technologies are suitable for forming fine bumps. Furthermore, they are capable of forming bumps collectively, so that a high productivity can be achieved. These technologies receive much attention as a mounting technology for a circuit board of the next generation LSI.

Specifically, a technology for forming bumps by printing and filling conductive resin on a protrusion formation plate provided with dents having the same size as that of the necessary bump, curing the conductive resin, and then bonding it to connection terminals of a thin film circuit element via the same conductive resin is disclosed in Japanese Patent Application Unexamined Publication No. H8-191072 (hereinafter, referred to as “patent document 1”).

Furthermore, in order to exclude a resin sealing step that increases the cost when a semiconductor element and a wiring board are connected to each other, a method for forming a bump having a tip by depositing a solder paste on an electrode pad of a semiconductor chip via a mask and curing thereof is disclosed in Japanese Patent Application Unexamined Publication No. H11-135549 (hereinafter, referred to as “patent document 2”).

Furthermore, when a semiconductor element having an area bump is mounted, high flatness is required with respect to the entire mounting area of a circuit board. Therefore, in order to use a circuit board with low flatness, a technology for forming an electrode bump of two layers, i.e., a lower bump and an upper bump having different elastic modulus is disclosed in Japanese Patent Application Unexamined Publication No. 2001-189337 (hereinafter, referred to as “patent document 3”).

Furthermore, a method for forming a solder bump by light-exposing and developing a predetermined portion of a semiconductor element coated with solder particles photosensitive resin in which solder particles are contained in photosensitive resin is disclosed in Japanese Patent Application Unexamined Publication No. H5-326524 (hereinafter, referred to as “patent document 4”). Thus, a solder bump having a structure in which solder particles are distributed in resin can be produced with high productivity. Furthermore, it discloses that a semiconductor element can be coupled to a wiring board with a solder bump by pressing the semiconductor element to the wiring board by a clamp.

In the conductive bumps described in the above-mentioned patent documents, a conductive paste containing a conductive filler is formed via a mask by screen printing. Therefore, the surface is a flat surface or a curve by the surface tension. Furthermore, in general, it is difficult to form conductive bumps having uniform height due to the thermal contraction of the contained resin and the like. Furthermore, in an electronic component mounting structure in which a semiconductor element is mounted on a circuit board via a non-conductive film (hereinafter, also referred to as an “NCF”), the semiconductor element needs to be connected to the connection terminal of the circuit board in which the conductive bump penetrates the NCF. At this time, in order to penetrate the NCF, or in order to realize uniform connection via conductive bumps having different heights, the semiconductor element is required to be brought into press contact with the circuit board with a high pressurizing force.

However, in a semiconductor element having a fragile insulating layer with low dielectric constant for increasing the performance, destruction or damage may occur due to press contact at the time of mounting. Furthermore, it is difficult to maintain the shape of a conductive bump and to realize a stable connection because of press contact with a high pressurizing force.

Furthermore, in the metal bump described in patent document 2, a metal bump is brought into press contact and electrically coupled to a wiring board in which a sharpened tip end of the metal bump penetrates the adhesive layer. However, when the wiring board and the semiconductor element are brought into press contact via a metal bump, in order to change the shape of the metal bump by press contact, a larger pressurizing force is necessary as compared with the case where resin-containing conductive bump is used. As a result, in a semiconductor element including a fragile insulating layer, the occurrence of the destruction or damage of the semiconductor element by stress at the time of press contact is further increased. Furthermore, since the shape of the metal bump is not easily changed, when the semiconductor element is mounted on a wiring board having a low flat accuracy via the metal bump, variation easily occurs in the connection resistance corresponding to the connection area according to the amount of the shape change in the tip portion of the metal bump.

### SUMMARY OF THE INVENTION

The present invention relates to a conductive bump formed on an electrode of an electronic component. The conductive bump includes a first bump having one or more layers formed on the electrode and including resin containing at least a spherical-shaped conductive filler, and a second bump formed on an upper surface of the first bump and including photosensitive resin containing a scale-shaped conductive filler.

With this configuration, since the second bump can penetrate a non-conductive film (NCF) with a low pressurizing force, it is possible to realize a conductive bump that can improve connection reliability at the time of mounting without damaging an insulating layer such as a dielectric layer of a semiconductor element as an electronic component.

Furthermore, the present invention relates to a method for forming a conductive bump formed on an electrode of an electronic component. The method includes (i) forming a first bump including resin containing a spherical-shaped conductive filler; and (ii) forming a second bump including photosensitive resin containing a scale-shaped conductive filler on the first bump. At least (ii) is carried out by using a stereo-lithography method. Thus, it is possible to form conductive bumps with uniform height with narrow pitch and with high productivity.

Furthermore, an electronic component mounting structure of the present invention includes at least, a semiconductor element having an electrode terminal, a circuit board having a connection terminal in a position facing the electrode terminal, and a resin layer provided between the electrode terminal of the semiconductor element and the connection terminal of the circuit board. The semiconductor element and the circuit board are connected to each other via the above-mentioned conductive bump provided on at least one of the electrode terminal and the connection terminal.

Thus, it is possible to realize an electronic component mounting structure with high connection strength and low connection resistance in which a semiconductor element with high flatness and a circuit board with high flatness are not needed.

### BRIEF DESCRIPTION OF THE DRAWINGS

FIG. 1A is a sectional view illustrating a structure of a conductive bump in accordance with a first exemplary embodiment of the present invention.

FIG. 1B is an enlarged sectional view of part A in FIG. 1A.

FIG. 2 is a flowchart illustrating a method for forming a conductive bump in accordance with the first exemplary embodiment of the present invention.

FIG. 3A is a sectional view illustrating a method for forming a first bump of the conductive bump in accordance with the first exemplary embodiment of the present invention.

FIG. 3B is a sectional view illustrating a method for forming a second bump of the conductive bump in accordance with the first exemplary embodiment of the present invention.

FIG. 4 is a sectional view showing a first modification of the conductive bump in accordance with the first exemplary embodiment of the present invention.

FIG. 5 is a sectional view illustrating a second modification of the conductive bump in accordance with the first exemplary embodiment of the present invention.

FIG. 6 is a sectional view showing a third modification of the conductive bump in accordance with the first exemplary embodiment of the present invention.

FIG. 7 is a sectional view showing a fourth modification of the conductive bump in accordance with the first exemplary embodiment of the present invention.

FIG. 8 is a sectional view illustrating a conductive bump in accordance with a second exemplary embodiment of the present invention.

FIG. 9A is a sectional view illustrating a method for forming a second bump of the conductive bump in accordance with the second exemplary embodiment of the present invention.

FIG. 9B is a sectional view illustrating a method for forming a first bump formed on the second bump of the conductive bump in accordance with the second exemplary embodiment of the present invention.

FIG. 9C is a sectional view illustrating a method for forming a second bump on the first bump of the conductive bump in accordance with the second exemplary embodiment of the present invention.

FIG. 10 is a sectional view illustrating a structure of a conductive bump in accordance with a third exemplary embodiment of the present invention.

FIG. 11A is a plan view illustrating a structure of a conductive bump in accordance with the third exemplary embodiment of the present invention.

FIG. 11B is a plan view illustrating another example of a structure of a conductive bump in accordance with the third exemplary embodiment of the present invention.

FIG. 12A is a sectional view showing a first modification of the second bump forming the conductive bump in accordance with the third exemplary embodiment of the present invention.

FIG. 12B is a sectional view showing a second modification of the second bump of the conductive bump in accordance with the third exemplary embodiment of the present invention.

FIG. 12C is a sectional view showing a third modification of the second bump of the conductive bump in accordance with the third exemplary embodiment of the present invention.

FIG. 13 is a flowchart illustrating a method for forming a conductive bump in accordance with the third exemplary embodiment of the present invention.

FIG. 14A is a sectional view illustrating a method for forming a first bump of a conductive bump in accordance with the third exemplary embodiment of the present invention.

FIG. 14B is a sectional view illustrating a method for forming a first bump of a conductive bump in accordance with the third exemplary embodiment of the present invention.

FIG. 14C is a sectional view illustrating a method for forming a first bump of a conductive bump in accordance with the third exemplary embodiment of the present invention.

FIG. 15A is a sectional view illustrating a method for forming a second bump of a conductive bump in accordance with the third exemplary embodiment of the present invention.

FIG. 15B is a sectional view illustrating a method for forming a second bump of a conductive bump in accordance with the third exemplary embodiment of the present invention.

FIG. 16 is a sectional view illustrating a structure of a case in which the first bumps of the conductive bump have different thickness in accordance with the third exemplary embodiment of the present invention.

FIG. 17A is a partial schematic sectional view illustrating an electronic component mounting structure and its manufacturing method in accordance with a fourth exemplary embodiment of the present invention.

FIG. 17B is a partial schematic sectional view illustrating an electronic component mounting structure and its manufacturing method in accordance with the fourth exemplary embodiment of the present invention.

FIG. 17C is a partial schematic sectional view illustrating an electronic component mounting structure and its manufacturing method in accordance with the fourth exemplary embodiment of the present invention.

FIG. 18A is a partial schematic sectional view illustrating an electronic component mounting structure in accordance with a fifth exemplary embodiment of the present invention.

FIG. 18B is a partial schematic sectional view illustrating an electronic component mounting structure in accordance with the fifth exemplary embodiment of the present invention.

FIG. 18C is a partial schematic sectional view illustrating an electronic component mounting structure in accordance with the fifth exemplary embodiment of the present invention.

### DETAILED DESCRIPTION OF THE INVENTION

Hereinafter, exemplary embodiments of the present invention are described with reference to drawings. The same reference numerals are given to the same configurations in the following exemplary embodiments and in each drawing.

### First Exemplary Embodiment

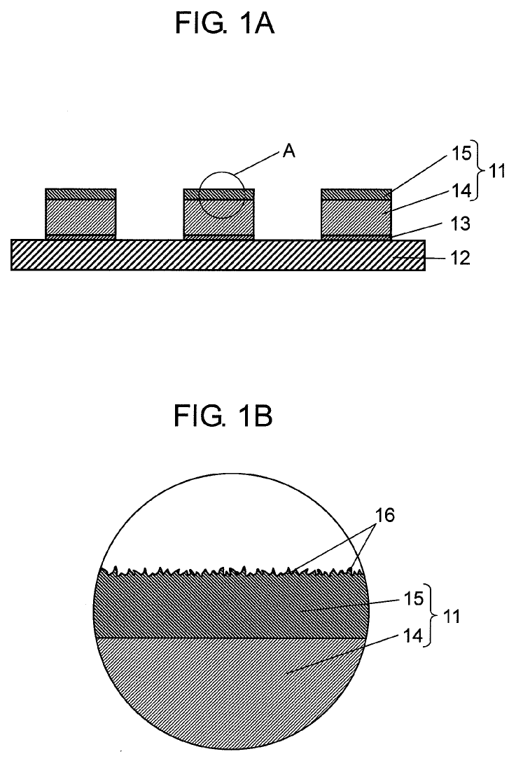

Hereinafter, with reference to FIGS. 1A and 1B, a structure of a conductive bump of a first exemplary embodiment of the present invention is described. Hereinafter, an example in which a semiconductor element is used as an electronic component and a conductive bump is formed on the semiconductor element is described. However, the same is true in the case in which a circuit board is used.

Furthermore, an electrode of the electronic component is expressed by using an electrode terminal for the semiconductor element and a connection terminal for the circuit board.

FIG. 1A is a sectional view illustrating a structure of a conductive bump in accordance with the first exemplary embodiment of the present invention. FIG. 1B is an enlarged sectional view of part A in FIG. 1A.

As shown in FIG. 1A, conductive bump 11 is provided on each of 100 μm×100 μm electrode terminals 13 disposed with a pitch of, for example, 150 μm on semiconductor element 12 including a semiconductor memory element such as ROM or RAM having an external size of, for example, 8 mm×8 mm.

Conductive bump 11 includes first bump 14 having a height of, for example, 20 μm to 50 μm, which is formed by a stereo-lithography method mentioned below in detail, and second bump 15 having a height of, for example, 5 μm to 10 μm, which is formed on the surface of first bump 14. Furthermore, first bump 14 of conductive bump 11 includes a conductive filler containing not less than 50 wt % and less than 80 wt % of spherical-shaped Ag particles as a main component in a resin paste containing photosensitive resin such as photosensitive polyimide resin as a main component. Furthermore, second bump 15 of conductive bump 11 includes a conductive filler containing not less than 50 wt % and less than 95 wt % of scale-shaped Ag particles as a main component into a resin paste containing photosensitive resin such as photosensitive polyimide resin as a main component.

At this time, as shown in FIG. 1B, on the uppermost layer surface of second bump 15 of conductive bump 11, protruding bodies 16 are formed at random. Protruding body 16 on second bump 15 is formed when, for example, the tip portion of the scale-shaped conductive filler kneaded in the photosensitive resin protrudes upright or obliquely in the forming direction and a part thereof is exposed at the time of photo-curing of the photosensitive resin by the below-mentioned stereo-lithography method.

As mentioned above, according to the conductive bump of this exemplary embodiment, in the below-mentioned electronic component mounting structure in which a semiconductor element and a circuit board are connected to each other via a resin layer such as a non-conductive film (NCF), since the second bump includes scale-shaped conductive fillers whose tip portion is exposed, it can penetrate the NCF with a low pressurizing force (pressing force). As a result, deformation of the conductive bump can be prevented and the shape of the conductive bump can be maintained stably because pressurizing force is low. Furthermore, connection with a low pressurizing force enables mounting in which damage of the semiconductor element or change in property of the semiconductor element does not easily occur. Furthermore, since a relatively soft conductive bump containing resin easily change its shape with a low pressurizing force particularly in the tip portion of protruding body 16, the electrode terminal of the semiconductor element can be connected to the connection terminal of the circuit board reliably. Similarly, since the shape of the conductive bump is easily changed, even when a circuit board with low flat accuracy having a concave/convex portion due to warp or deformation is used, the semiconductor element can be mounted on the circuit board reliably.

Furthermore, in accordance with this exemplary embodiment, the principal part of conductive bump 11 includes first bump 14 containing spherical-shaped conductive fillers whose rigidity can be made to be relatively high and whose specific resistance is low, and second bump 15 having a rough surface on the uppermost layer surface in which scale-shaped conductive fillers are exposed. At this time, first bump 14 can increase the transmittance of ultraviolet light in the stereo-lithography method because spherical-shaped conductive fillers are contained. Therefore, an excellent structure with high mechanical strength can be formed. Thus, it is possible to realize a conductive bump having an excellent shape stability and high penetration with respect to an NCF.

Herein, as semiconductor element 12, functional elements including a high-density integrated circuit element such as an LSI chip and a mass storage element such as a memory are used. At this time, electrode terminal 13 of semiconductor element 12 is formed by forming 0.1 μm to 0.3 μm Ni barrier layer (not shown) on, for example, an Al electrode that is an opening from which a part of wiring (not shown), patterned so that an area bump can be disposed, is exposed. Metal such as Au and Cu can be appropriately used for a material of electrode terminal 13, and metal such as Ti, Cr and W can be appropriately used as a metal barrier layer.

In this exemplary embodiment, an example in which Ag particles or Ag powder is used as the conductive filler forming the first bump and the second bump is described. However, the configuration is not necessarily limited to this example. For example, at least any of at least one powder of metal selected from Au, Cu and Pt, or at least one solder alloy selected from an Sn—Ag—In alloy, an Sn—Pb alloy, an Sn—Ag alloy, an Sn—Ag—Bi alloy, an Sn—Ag—Bi—Cu alloy, an Sn—Ag—In—Bi alloy, a Zn—In alloy, an Ag—Sn—Cu alloy, an Sn—Zn—Bi alloy, an In—Sn alloy, an In—Bi—Sn alloy and an Sn—Bi alloy may be used.

Furthermore, in this exemplary embodiment, an example in which a spherical-shaped conductive filler is used as the conductive filler of the first bump is described. However, the configuration is not necessarily limited to this example, a part of the conductive fillers may be substituted with spherical-shaped conductive fillers.

Furthermore, in this exemplary embodiment, an example in which a scale-shaped conductive filler is used as the conductive filler of the second bump is described. However, the configuration is not necessarily limited to this example, a part of the conductive fillers may be substituted with scale-shaped conductive fillers.

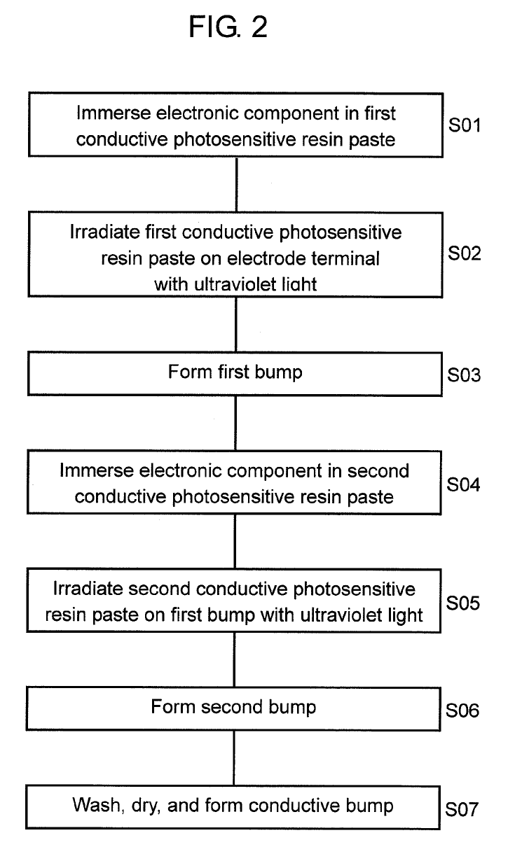

Hereinafter, an outline of a method for forming a conductive bump in accordance with the first exemplary embodiment of the present invention is described with reference to FIG. 2. Similar to the above, in this description, a semiconductor element is used as the electronic component.

FIG. 2 is a flowchart illustrating a method for forming a conductive bump in accordance with the first exemplary embodiment of the present invention.

Firstly, a semiconductor element is immersed in a container, which is filled with a first conductive photosensitive resin paste containing a spherical-shaped conductive filler, with an electrode terminal formed on the semiconductor element facing upward (step S01). At this time, the first conductive photosensitive resin paste includes photosensitive resin including, for example, a photosensitive/thermoplastic acrylic oligomer, an acrylic monomer, an initiator, a coupling agent, an adhesiveness-imparting agent, a reactive diluent, a solvent, and the like, and spherical-shaped conductive fillers including not less than 50 wt % and less than 80 wt % of Ag particles.

Next, for example, a liquid crystal mask is used as a photomask, and the first photosensitive conductive resin paste on the electrode terminal is irradiated with ultraviolet light, visible light, or the like, for curing the photosensitive resin of the first photosensitive conductive resin paste, via an opening of the photomask by a stereo-lithography method (step S02). At this time, the first conductive photosensitive resin paste is irradiated with ultraviolet light, visible light, or the like, from the opening of the photomask controlled based on three-dimensional CAD data, for example, while the semiconductor element is continuously moved down into the first conductive photosensitive resin paste, or in a state in which the semiconductor element is submerged in a predetermined depth. Thus, the first bump is formed to a predetermined thickness on the electrode terminal of the semiconductor element (step S03). Then, the semiconductor element is taken out from the container and attached unexposed first conductive photosensitive resin paste is washed.

Next, the semiconductor element is immersed in a container, which is filled with a photo-curable second conductive photosensitive resin paste containing a scale-shaped conductive filler, with the first bump side of the semiconductor element facing upward (step S04). At this time, the second conductive photosensitive resin paste includes the same photosensitive resin as that in the first conductive photosensitive resin paste and scale-shaped conductive fillers including not less than 50 wt % and less than 95 wt % of Ag particles.

Next, the second photosensitive conductive resin paste on the first bump is irradiated with ultraviolet light, visible light, or the like, for curing the photosensitive resin of the second conductive photosensitive resin paste on the first bump via an opening of the photomask by a stereo-lithography method (step S05). At this time, the second conductive photosensitive resin paste is irradiated with ultraviolet light, visible light, or the like, from the opening of the photomask controlled based on three-dimensional CAD data, for example, while the semiconductor element is continuously moved down into the second conductive photosensitive resin paste, or in a state in which the semiconductor element is submerged in a predetermined depth. Thus, the second bump is formed to a predetermined thickness on the first bump of the semiconductor element (step S06).

Next, the semiconductor element is taken out from the container, and attached unexposed second conductive photosensitive resin paste is washed, removed, and then dried. Thus, a conductive bump including the first bump and the second bump is formed (step S07).

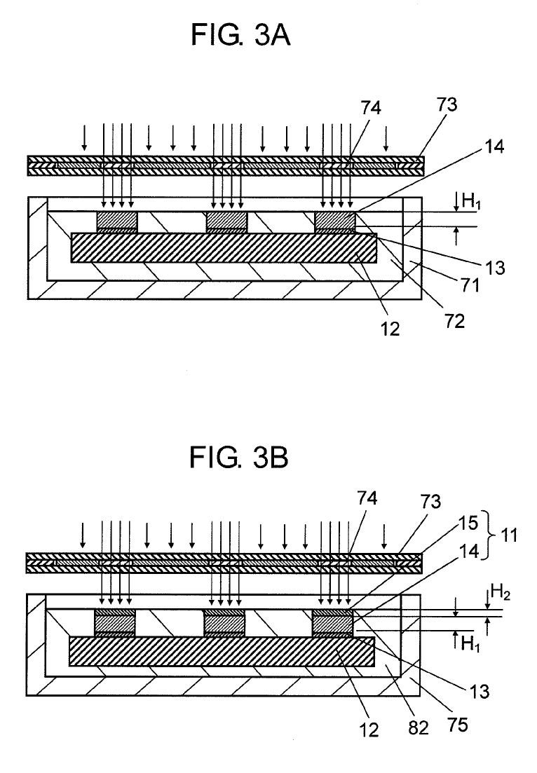

Hereinafter, a method for forming the conductive bump in accordance with the first exemplary embodiment of the present invention is described with reference to FIGS. 3A and 3B. Note here that as the electronic component, a semiconductor element is described as an example. The same reference numerals are given to the same components.

FIG. 3A is a sectional view illustrating a method for forming the first bump of the conductive bump in accordance with the first exemplary embodiment of the present invention. FIG. 3B is a sectional view illustrating a method for forming the second bump of the conductive bump in accordance with the first exemplary embodiment of the present invention.

Firstly, as shown in FIG. 3A, first conductive photosensitive resin paste 72 including, for example, photosensitive resin (acrylate-based resin) as a resin component and 50 wt % to 95 wt % of spherical-shaped Sn—Ag—In alloy particles as a conductive filler is filled in container 71.

Then, semiconductor element 12 disposed on a stage (not shown) is immersed in first conductive photosensitive resin paste 72 until the upper surface of electrode terminal 13 of semiconductor element 12 comes in a position with a predetermined interval H₁ (for example, 30 μm to 50 μm) from the liquid surface of first conductive photosensitive resin paste 72.

Next, a predetermined region of the first photosensitive resin paste is irradiated with ultraviolet light or visible light and exposed to the light via opening 74 of photomask 73 made of, for example, a liquid crystal panel, and first bump 14 is formed on electrode terminal 13 to height H₁. At this time, first bump 14 is formed by irradiation with ultraviolet light or visible light from opening 74 of photomask 73 controlled based on three-dimensional CAD data. Note here that an example in which first bump 14 is formed in a state in which the semiconductor element is submerged in predetermined depth H₁ in first conductive photosensitive resin paste 72 is described. However, first bump 14 may be formed while the semiconductor element is continuously moved down.

Next, semiconductor element 12 on which first bump 14 is formed is taken out from container 71, and unexposed first conductive photosensitive resin paste 72 is removed, washed and dried.

Next, as shown in FIG. 3B, second conductive photosensitive resin paste 82 including, for example, photosensitive resin (epoxy-based resin) as a resin component and 50 wt % to 80 wt % of scale-shaped Ag powder (minor axis: 0.2 μm to 1 μm, major axis: 2 μm to 5 μm) as a conductive filler is filled in container 75.

Then, semiconductor element 12 on which first bump 14 is formed on electrode terminal 13 with predetermined height H₁ is immersed in second conductive photosensitive resin paste 82 until the upper surface of first bump 14 of semiconductor element 12 comes in a position with interval H₂ (for example, 5 μm to 10 μm) from the liquid surface of second conductive photosensitive resin paste 82.

Next, similar to the case of first bump 14, second conductive photosensitive resin paste 82 on the upper surface of first bump 14 is irradiated with ultraviolet light and exposed to light via opening 74 of photomask 73 and second bump 15 is continuously formed to predetermined height H₂. At this time, second bump 15 is formed by irradiation with ultraviolet light or visible light from opening 74 of photomask 73 controlled based on three-dimensional CAD data. Note here that an example in which second bump 15 is formed in a state in which the semiconductor element is submerged in predetermined depth H₁ in second conductive photosensitive resin paste 82 is described. However, second bump 15 may be formed while the semiconductor element is continuously moved down.

On the surface of second bump 15, one end of the scale-shaped conductive filler is exposed upright or obliquely as generally described with reference to FIG. 1B, so that protruding bodies 16 are formed and the surface is roughened. The surface of second bump 15 can be roughened in arbitrary shapes according to design of CAD data and control data. Furthermore, the rigidity or the surface state of second bump 15 can be arbitrarily set by adjusting the amount of photosensitive resin or conductive fillers by considering the material, the thickness of NCF, and the like, when, for example, an electronic component mounting structure is formed.

Next, on the surface of electrode terminal 13 of semiconductor element 12, conductive bump 11 including first bump 14 containing spherical-shaped conductive fillers and second bump 15 containing scale-shaped conductive fillers formed on first bump 14 is formed. Then, semiconductor element 12 is taken out from container 75 filled with second conductive photosensitive resin paste 82, washed and dried.

By the above-mentioned forming method, on electrode terminal 13 of semiconductor element 12, conductive bump 11 including first bump 14 and second bump 15 on which one end of the scale-shaped conductive fillers are exposed is formed.

In this exemplary embodiment, an example in which a conductive bump is formed on the electrode terminal of the semiconductor element is described. The configuration is not necessarily limited to this example. For example, a conductive bump may be also formed by the similar forming method on a connection terminal of the circuit board provided with a wiring pattern.

According to the forming method of this exemplary embodiment, a conductive bump including a first bump having excellent conductivity and shape stability and a second bump capable of penetrating a resin layer such as an NCF with a low pressurizing force (pressing force) by an exposed tip portion of scale-shaped conductive fillers can be easily produced with a narrow pitch. As a result, with a low pressurizing force, deformation of the conductive bump can be prevented and the shape of the conductive bump can be stably maintained. Furthermore, connection with a low pressurizing force enables mounting in which damage of the semiconductor element or the change in property of the semiconductor element does not easily occur.

According to the forming method of this exemplary embodiment, regardless of concavity and convexity on a forming surface due to warp or deformation, which has been a problem of a conventional metal bump or a conductive bump by a screen printing method, it is possible to form a conductive bump having a uniform surface over the entire forming surface. As a result, when an electronic component mounting structure is produced, mounting with a low pressurizing force can be realized and connection reliability can be improved. Furthermore, a conductive bump having an excellent reliability in which element cracking of the semiconductor element or destruction of an insulating layer due to a pressurizing force is not easily occur can be produced.

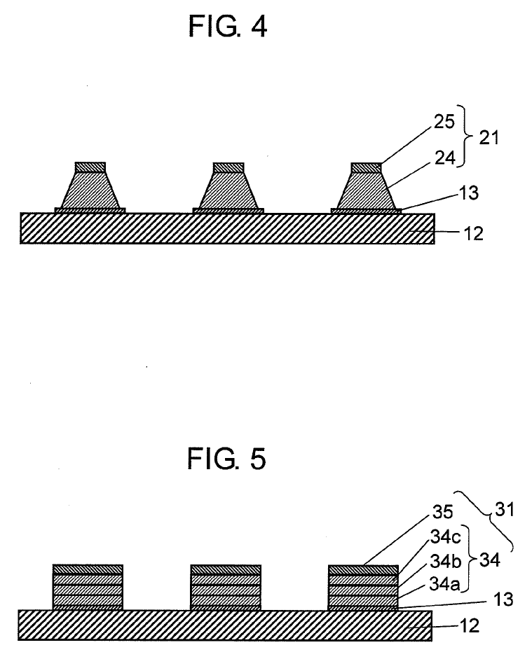

In this exemplary embodiment, an example in which a first bump and a second bump are composed of one layer respectively, and a conductive bump has a square sectional shape is described. However, a configuration is not necessarily limited to this example. The first and second bumps may be composed of one or more layers. Herein, modifications of the conductive bump of this exemplary embodiment are described with reference to FIGS. 4 to 7.

Firstly, FIG. 4 is a sectional view showing a first modification of the conductive bump in accordance with the first exemplary embodiment of the present invention.

As shown in FIG. 4, first bump 24 of conductive bump 21 is formed to have a trapezoid sectional shape on electrode terminal 13 of semiconductor element 12. Then, second bump 25 is formed on the uppermost surface of first bump 24. Thus, conductive bump 21 is produced. Thus, since a pressurizing force can be concentrated on a relatively small area when a mounting structure is produced, the conductive bump can penetrate the NCF easily.

Hereinafter, a method for forming conductive bump 21 shown in FIG. 4 is briefly described with reference to FIGS. 3A and 3B. That is to say, first bump 24 of conductive bump 21 is formed in a trapezoid shape by narrowing an opening area of opening 74 of photomask 73 shown in FIG. 3A in synchronization with the speed at which semiconductor element 12 is submerged in first conductive photosensitive resin paste 72 and carrying out light-exposure. Since the other forming method is the same as that for conductive bump 11, the description is omitted herein.

Furthermore, FIG. 5 is a sectional view showing a second modification of the conductive bump in accordance with the first exemplary embodiment of the present invention.

As shown in FIG. 5, first bump 34 of conductive bump 31 is formed on electrode terminal 13 of semiconductor element 12, in which, for example, a plurality of layers including first layer 34a, second layer 34b, third layer 34c, and the like, are formed step by step. Then, second bump 35 is formed on the uppermost surface of third layer 34c in the plurality of layers. Thus, conductive bump 31 is produced.

Thus, since the first bump is formed of a plurality of layers, the decrease (attenuation) in the amount of transmitted light of ultraviolet light or visible light can be suppressed, thus enabling the curing degree of the photosensitive resin paste to be enhanced. As a result, the mechanical strength of first bump 34 can be improved so as to enhance the shape stability. That is to say, for example, when the thickness of the first bump is thick, the amount of ultraviolet light or visible light to be transmitted in the direction of the thickness of the first bump is limited (reduced) by conductive fillers, and the curing of the photosensitive resin in the vicinity of the electrode terminal is suppressed. However, when the first bump is formed of a plurality of layers, by reducing the thickness of each layer, an effect of curing with sufficient ultraviolet light or visible light can be obtained.

Hereinafter, a method for forming conductive bump 31 shown in FIG. 5 is briefly described with reference to FIGS. 3A and 3B. That is to say, first bump 34 of conductive bump 31 is formed as follows. Firstly, semiconductor element 12 is submerged in first conductive photosensitive resin paste 72 to the depth corresponding to the thickness of first layer 34a. Then, first conductive photosensitive resin paste 72 is exposed to light via opening 74 of photomask 73 shown in FIG. 3A, thus forming first layer 34a. By repeating the same method, second layer 34b and third layer 34c are formed. Thus, first bump 34 of conductive bump 31 correspond to first bump 14 of conductive bump 11 in the first exemplary embodiment is produced. Since the other forming method is the same as that of conductive bump 11, the description thereof is omitted herein.

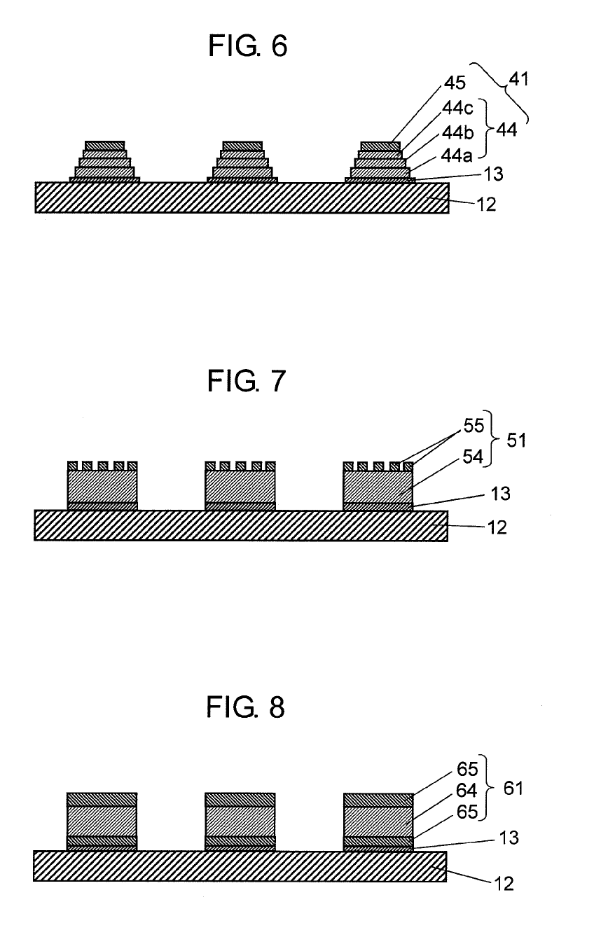

Furthermore, FIG. 6 is a sectional view showing a third modification of the conductive bump in accordance with the first exemplary embodiment of the present invention.

As shown in FIG. 6, first bump 44 of conductive bump 41 is formed to have a trapezoid sectional shape on electrode terminal 13 of semiconductor element 12, in which, for example, a plurality of layers including first layer 44a, second layer 44b, and third layer 44c, are formed in stages. Then, second bump 45 is formed on the uppermost surface of third layer 44c in the plurality of layers. Thus, conductive bump 41 is produced.

Thus, in first bump 44, a plurality of layers can improve the mechanical strength and increase the shape stability. In addition, since first bump 44 has a trapezoid shape, it can penetrate an NCF with a lower pressurizing force.

Hereinafter, a method for forming conductive bump 41 shown in FIG. 6 is briefly described with reference to FIGS. 3A and 3B. That is to say, first bump 44 of conductive bump 41 is formed as follows. Firstly, semiconductor element 12 is submerged in first conductive photosensitive resin paste 72 to a predetermined depth corresponding to the thickness of first layer 44a. Then, first conductive photosensitive resin paste 72 is exposed to light via opening 74 of photomask 73 shown in FIG. 3A. Thus, first layer 44a is formed. Next, by repeating the same method while an opening area of opening 74 of photomask 73 is sequentially narrowed, second layer 44b and third layer 44c are formed. Thus, first bump 44 of conductive bump 41 correspond to first bump 14 of conductive bump 11 in the first exemplary embodiment is produced. Since the other forming method is the same as that for conductive bump 11, the description thereof is omitted herein.

Furthermore, FIG. 7 is a sectional view showing a fourth modification of the conductive bump in accordance with the first exemplary embodiment of the present invention.

As shown in FIG. 7, conductive bump 51 is different from conductive bump 11 shown in FIG. 1A in that a plurality of second bumps 55 of conductive bump 51 are independently formed so as to form protruding portions. Thus, a penetrating force with respect to a resin layer such as an NCF can be further improved.

Hereinafter, a method for forming conductive bump 51 shown in FIG. 7 is briefly described with reference to FIGS. 3A and 3B. Second bump 55 of conductive bump 51 is formed as follows. Firstly, semiconductor element 12 provided with first bump 54 is submerged in second conductive photosensitive resin paste 82 to a predetermined depth corresponding to the thickness of second bump 55 from the liquid surface. Then, openings 74 of photomask 73 shown in FIG. 3B are opened corresponding to the independent protruding portions, and second conductive photosensitive resin paste 82 is exposed to light via openings 74 of photomask 73 shown in FIG. 3B. Thus, second bump 55 is produced. Since the other forming method is the same as that for conductive bump 11, the description thereof is omitted herein.

Needless to say, a configuration of the second bump of the fourth modification can be applied to the first exemplary embodiment and the first to third modifications. Furthermore, the sectional shape of the protruding portion is not necessarily limited to a square shape. For example, the sectional shape may be, for example, triangle, trapezoid, or the like. Furthermore, the shapes of the plurality of protruding portions may not be the same as each other. Different shaped protruding portions may be provided on the first bump. Furthermore, a second bump may be formed of a plurality of protruding portions having different heights.

In this exemplary embodiment, an example in which the second bump is formed on the entire surface of the first bump, that is, the second bump and the first bump have the same area is described. However, the configuration is not necessarily limited to this example. For example, the second bump may be formed with the peripheral part of the upper surface of the first bump left, so that the area of the second bump is made to be smaller than that of the first bump. Thus, the conductive bump can penetrate the NCF with a lower pressurizing force.

### Second Exemplary Embodiment

Hereinafter, a conductive bump in accordance with a second exemplary embodiment of the present invention is described with reference to FIG. 8.

FIG. 8 is a sectional view illustrating a conductive bump in accordance with the second exemplary embodiment of the present invention. The conductive bump of this exemplary embodiment is different from conductive bump 11 of the first exemplary embodiment in that second bump 65 is provided not only on the upper surface of first bump 64 but also on electrode terminal 13 of semiconductor element 12.

That is to say, as shown in FIG. 8, conductive bump 61 is formed in a state in which first bump 64 including a spherical-shaped conductive filler and photosensitive resin is sandwiched between second bumps 65 including a scale-shaped conductive filler and photosensitive resin. Thus, since the connection resistance of semiconductor element 12 with respect to electrode terminal 13 can be reduced by the scale-shaped conductive filler, conductive bump 61 with a high conductivity can be realized.

According to the conductive bump of this exemplary embodiment, the connection resistance can be reduced by the second bump connected to the electrode terminal. Furthermore, with the first bump having a predetermined thickness or more and containing scale-shaped conductive fillers, excellent shape-stability and high conductivity of the conductive bump itself can be realized. In addition, with the second bump provided on the uppermost surface of the first bump, penetration force with respect to a resin layer such as an NCF is improved, thus enabling the connection with respect to other electronic components such as a circuit board with a low pressurizing force.

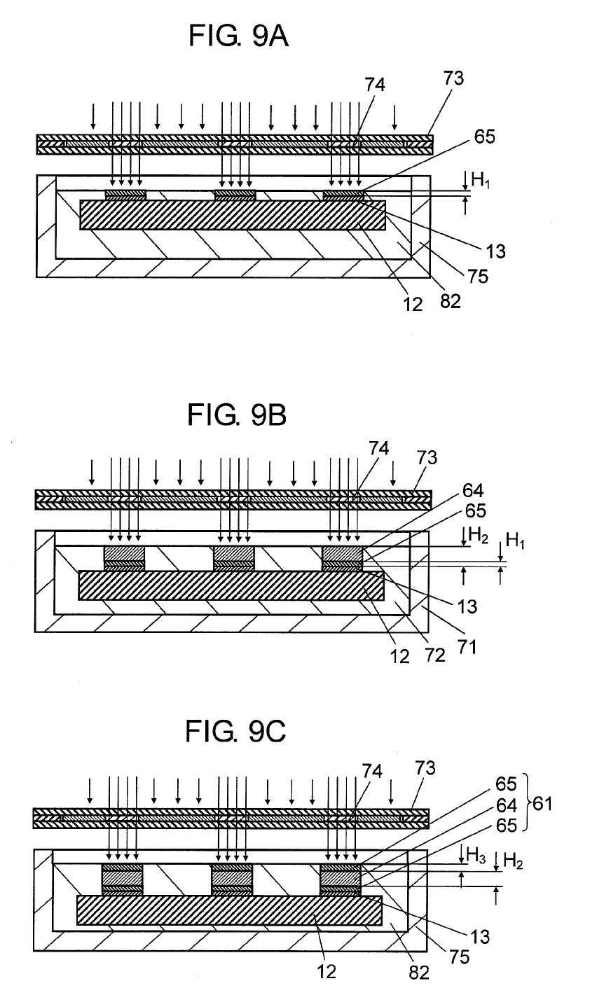

Hereinafter, a method for forming a conductive bump in accordance with the second exemplary embodiment of the present invention is described with reference to FIGS. 9A to 9C. Basically, since the method is the same as that of the conductive bump of the first exemplary embodiment, the description thereof may be omitted.

FIG. 9A is a sectional view illustrating a method for forming a second bump of the conductive bump in accordance with the second exemplary embodiment of the present invention. FIG. 9B is a sectional view illustrating a method for forming a first bump formed on the second bump of the conductive bump in accordance with the second exemplary embodiment of the present invention. FIG. 9C is a sectional view illustrating a method for forming a second bump formed on the first bump of the conductive bump in accordance with the second exemplary embodiment of the present invention.

Firstly, as shown in FIG. 9A, second conductive photosensitive resin paste 82 including, for example, photosensitive resin (epoxy-based resin) as a resin component and 50 wt % to 95 wt % of scale-shaped Ag powder (minor axis: 0.2 μm to 1 μm, major axis: 2 μm to 5 μm) as a conductive filler is filled in container 75.

Then, semiconductor element 12 disposed on a stage (not shown) is immersed in second conductive photosensitive resin paste 82 with electrode terminal 13 facing upward.

Next, a predetermined region of second conductive photosensitive resin paste 82 is irradiated with, for example, ultraviolet light and exposed to the light via opening 74 of photomask 73 made of, for example, a liquid crystal panel, so that second bump 65 is formed on electrode terminal 13 with height H₁ (for example, several μm to 10 μm). At this time, second bump 65 is formed by irradiation with ultraviolet light from opening 74 of photomask 73 controlled based on three-dimensional CAD data. Note here that an example in which second bump 65 is formed in a state in which the semiconductor element is submerged in predetermined depth H₁ in second conductive photosensitive resin paste 82 is described. However, second bump 65 may be formed while the semiconductor element is continuously moved down.

Then, semiconductor element 12 on which second bump 65 is formed is taken out from container 75, and attached unexposed second conductive photosensitive resin paste 82 is removed, washed and dried.

Next, as shown in FIG. 9B, first conductive photosensitive resin paste 72 including, for example, photosensitive resin (acrylate-based resin) as a resin component and 50 wt % to 80 wt % of spherical-shaped Sn—Ag—In alloy particles as a conductive filler is filled in container 71.

Then, semiconductor element 12 is immersed in first conductive photosensitive resin paste 72 until the upper surface of second bump 65 formed on electrode terminal 13 of semiconductor element 12 comes in a position with a predetermined interval H₂ (for example, 30 μm to 50 μm) from the liquid surface of first conductive photosensitive resin paste 72.

Next, a predetermined region of first conductive photosensitive resin paste 72 is irradiated with, for example, ultraviolet light and exposed to the light via opening 74 of photomask 73 made of, for example, a liquid crystal panel, and first bump 64 is formed on second bump 65 to height H₂. At this time, first bump 64 is formed by irradiation with ultraviolet light or visible light from opening 74 of photomask 73 controlled based on three-dimensional CAD data. Note here that an example in which first bump 64 is formed in a state in which the semiconductor element is submerged in predetermined depth H₂ in first conductive photosensitive resin paste 72 is described. However, first bump 64 may be formed while the semiconductor element is continuously moved down.

Semiconductor element 12 on which first bump 64 is formed on second bump 65 is taken out from container 71, and attached unexposed first conductive photosensitive resin paste 72 is removed, washed and dried.

Next, as shown in FIG. 9C, semiconductor element 12 on which first bump 64 is formed with predetermined height H₂ is immersed again in second conductive photosensitive resin paste 82 in container 75.

Next, similar to the case of second bump 65 on electrode terminal 13, irradiation with, for example, ultraviolet light is carried out via opening 74 of photomask 73. Thus, second conductive photosensitive resin paste 82 on the upper surface of first bump 64 is exposed to light, so that second bump 65 having predetermined height H₃ (for example, several μm to 10 μm) is formed.

Herein, at least the uppermost surface of second bump 65 is generally roughened by protruding bodies 16 in which one end of the scale-shaped conductive filler is exposed upright or obliquely as described with reference to FIG. 1B. The uppermost surface of second bump 65 can be roughened in arbitrary shapes according to the design of CAD data and control data. Furthermore, the rigidity and the surface state of second bump 65 can be arbitrarily set by adjusting the amount of photosensitive resin or a conductive filler by considering the material and the thickness of the NCF, and the like, when, for example, an electronic component mounting structure is formed.

Next, semiconductor element 12 is taken out from container 75 filled with second conductive photosensitive resin paste 82, washed, and dried.

With the above-mentioned forming method, conductive bump 61 including at least three layers, i.e., second bump 65, first bump 64 and second bump 65 is formed on electrode terminal 13 of semiconductor element 12.

In this exemplary embodiment, an example in which a conductive bump is formed on an electrode terminal of a semiconductor element is described. However, the configuration is not necessarily limited to this example. For example, a conductive bump may be formed also on a connection terminal of a circuit board provided with a wiring pattern by the similar forming method.

Furthermore, in this exemplary embodiment, an example in which the same material is used as the second conductive photosensitive resin paste forming the second bump is described. However, the material is not particularly limited to this example and a material containing a spherical-shaped conductive filler may be used as long as the material contains a scale-shaped conductive filler.

Furthermore, in this exemplary embodiment, an example in which the thickness of the second bump is equal is described. However, the configuration is not necessarily limited to this example, and the thickness may be different.

Furthermore, in this exemplary embodiment, an example in which a conductive bump has a square sectional shape is described. However, the shape is not necessarily limited to square shape. For example, the conductive bump may have shapes described with reference to FIGS. 4 to 7 in the first exemplary embodiment.

### Third Exemplary Embodiment

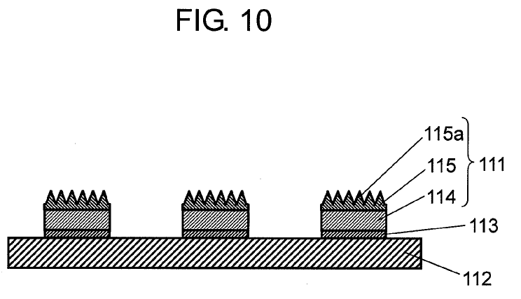

Hereinafter, a structure of a conductive bump in accordance with a third exemplary embodiment of the present invention is described with reference to FIG. 10. Hereinafter, similar to the first exemplary embodiment, an example in which a semiconductor element is used as an electronic component and a conductive bump is formed on the semiconductor element is described. However, the same is true in the case in which a circuit board is used. Since a configuration of the semiconductor element, a material of conductive filler forming the conductive bump, a shape, and materials of resin or photosensitive resin, and the like, are the same as those in the first exemplary embodiment, the description thereof is omitted herein.

Furthermore, an electrode of the electronic component is expressed by using an electrode terminal for the semiconductor element and a connection terminal for the circuit board.

FIG. 10 is a sectional view illustrating a structure of a conductive bump in accordance with the third exemplary embodiment of the present invention.

As shown in FIG. 10, conductive bump 111 is provided on each of 100 μm×100 μm electrode terminals 113 disposed with a pitch of, for example, 150 μm on semiconductor element 112 including a semiconductor memory element such as ROM or RAM having an external size of, for example, 8 mm×8 mm.

Conductive bump 111 includes first bump 114 having a height of, for example, 20 μm to 50 μm, which is formed by a printing method mentioned below in detail, and second bump 115 having a height of, for example, 5 μm to 10 μm, which has a plurality of, for example, pyramid-shaped protruding portions 115a, on the surface formed on first bump 114 by a stereo-lithography method. Furthermore, first bump 114 of conductive bump 111 includes at least resin containing, for example, epoxy resin as an main component, and a conductive filler containing not less than 50 wt % and less than 80 wt % of spherical-shaped Ag particles as a main component. Furthermore, second bump 115 of conductive bump 111 includes at least photosensitive resin containing, for example, photosensitive polyimide resin as a main component and conductive fillers containing not less than 50 wt % and less than 95 wt % of scale-shaped Ag particles as a main component.

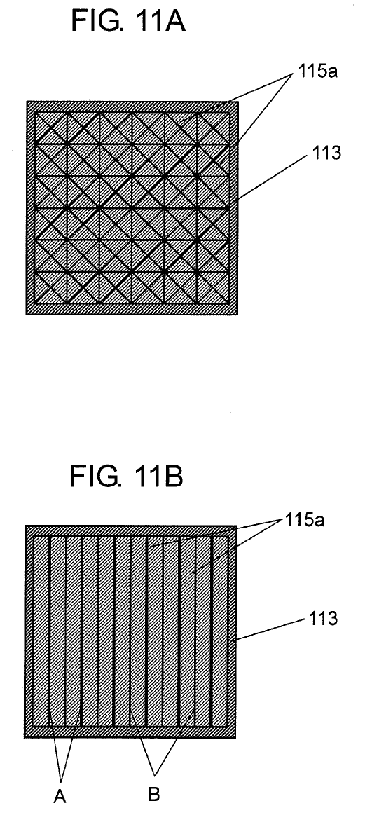

At this time, pyramid-shaped protruding portions 115a of second bump 115 are formed in a lattice on the first bump of electrode terminal 113 as shown in FIG. 11A. As shown in FIG. 11B, a protruding portion may have ridge line A continuing along any directions of longitudinally, laterally and obliquely on a first bump surface of electrode terminal 113, or may be formed spirally. Herein, B shown in this drawing represents a trough line between ridge lines A-A.

As mentioned above, according to the conductive bump of this exemplary embodiment, in the below-mentioned electronic component mounting structure in which a semiconductor element and a circuit board are connected to each other via a resin layer such as a non-conductive film (NCF), protrusion portion 115a of the second bump can penetrate the NCF with a low pressurizing force (pressing force). As a result, because the pressurizing force is low, deformation of the conductive bump can be prevented and the shape of the conductive bump can be maintained stably. Furthermore, by the connection with a low pressurizing force, mounting can be realized in which damage of the semiconductor element or change in property in the semiconductor element does not easily occur. Furthermore, since a relatively soft conductive bump containing resin easily change its shape with a low pressurizing force particularly in the tip portion of protruding portion 115a, the electrode terminal of the semiconductor element can be reliably connected to the connection terminal of the circuit board. Similarly, since the shape of the conductive bump is easily changed, even when a circuit board with low flat accuracy having a concave/convex portion due to warp or deformation is used, the semiconductor element can be mounted on the circuit board reliably.

In this exemplary embodiment, an example in which the second bump is provided with protruding portions is described. However, the configuration is not necessarily limited to this example. For example, similar to the first exemplary embodiment, when a conductive filler of the second bump is a scale-shaped filler, the protruding portion is not particularly needed to be formed. This is because concavity and convexity are formed on the surface of the second bump with scale-shaped conductive fillers and the concave/convex portion can penetrate the NCF. However, since concavity and convexity are not easily formed when most of conductive fillers of the second bump are formed of spherical-shaped fillers, it is preferable that protruding portions are formed on the second bump.

Furthermore, in this exemplary embodiment, an example in which the second bump is formed on the upper surface of the first bump and the first bump and the second bump have the same area is described. However, the configuration is not necessarily limited to this example. For example, the second bump having a smaller area than that of the upper surface of the first bump may be formed. Thus, the second bump can penetrate the NCF with a lower pressurizing force.

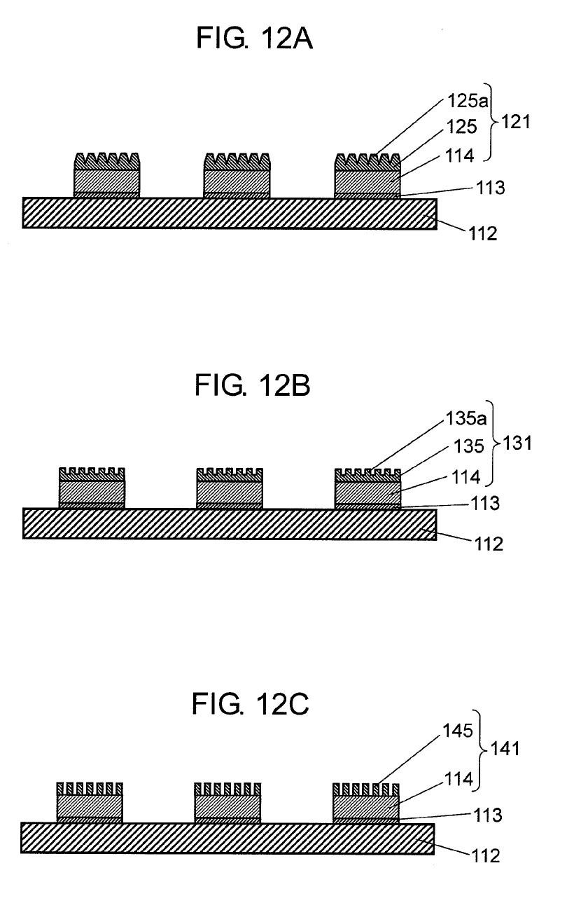

Furthermore, in this exemplary embodiment, an example in which a pyramid-shaped protruding portion has a triangular sectional shape is described. However, the shape is not necessarily limited to this example. Hereinafter, in particular, modifications of the protruding portion are described with reference to FIGS. 12A to 12C.

FIGS. 12A to 12C are sectional views showing the first to third modifications of a second bump forming a conductive bump in accordance with the third exemplary embodiment of the present invention. At this time, similar to the third exemplary embodiment, first bump 114 is provided on electrode terminal 113 of semiconductor element 112 by a printing method such as screen printing.

Firstly, FIG. 12A is a sectional view showing a first modification of the second bump in which conductive bump 121 includes second bump 125 having a plurality of protruding portions 125a whose sectional shape is trapezoid on the upper surface of first bump 114.

Furthermore, FIG. 12B is a sectional view showing a second modification of the second bump in which conductive bump 131 includes second bump 135 having a plurality of protruding portions 135a whose sectional shape is square on the upper surface of first bump 114.

Furthermore, FIG. 12C is a sectional view showing a third modification of the second bump. Conductive bump 141, in which a plurality of second bumps 145 having a square sectional shape are provided independently on the upper surface of first bump 114, is formed. That is to say, second bump 145 is different from second bumps 115, 125 and 135 in that protruding portions 115a, 125a and 135a are integrated. Note here that second bump 145 may have any shapes selected from a cylindrical shape, a pyramid shape, a cone shape, and a trapezoid shape. Any shapes can be taken as long as they can form concavity and convexity.

Needless to say, plan arrangement of protruding portion 115a shown in FIGS. 11A and 11B may be applied to the first, second and third modifications.

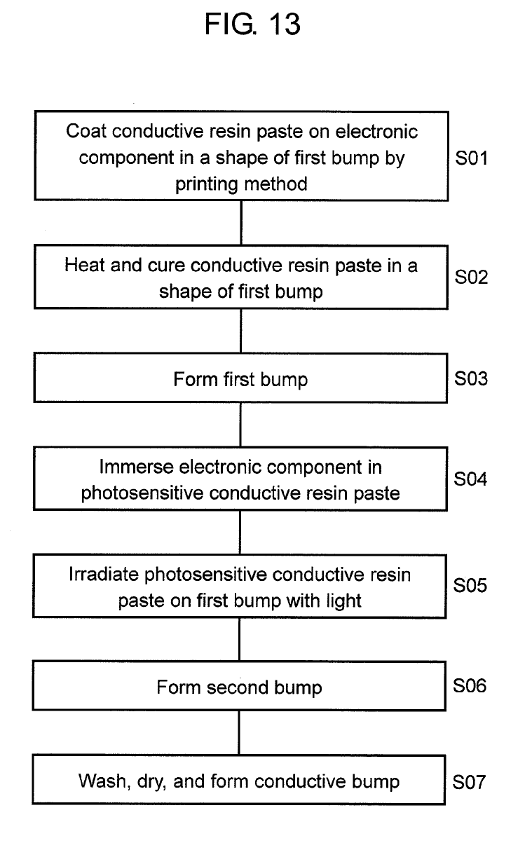

Hereinafter, an outline of a method for forming a conductive bump in accordance with the third exemplary embodiment of the present invention is described with reference to FIG. 13.

FIG. 13 is a flowchart illustrating a method for forming a conductive bump in accordance with the third exemplary embodiment of the present invention.

Firstly, a conductive resin paste obtained by mixing resin including thermosetting resin such as epoxy resin as a main component with conductive fillers such as spherical-shaped Ag powder is printed and coated on an electrode terminal of a semiconductor element in a shape of the first bump (step S01).

Next, a conductive resin paste in a shape of the first bump is heated and cured on the electrode terminal that is pattern-formed by printing (step S02). When the photosensitive resin is used as resin, the resin is irradiated with ultraviolet light, visible light, or the like, so as to be cured. Thus, the first bump is formed of the electrode terminal of the semiconductor element (step S03).

Next, a semiconductor element provided with the first bump is immersed in a container filled with a photocurable photosensitive conductive resin paste containing not less than 50 wt % and less than 95 wt % of scale-shaped Ag particles as a conductive filler in photosensitive resin including, for example, a photosensitive/thermoplastic acrylic oligomer, an acrylic monomer, an initiator, a coupling agent, an adhesiveness-imparting agent, a reactive diluent, a solvent, and the like, with the electrode terminal facing upward (step S04).

Next, for example, a liquid crystal mask is used as a photomask and a photosensitive conductive resin paste on the first bump is irradiated with ultraviolet light, visible light, or the like, via an opening of the photomask by a stereo-lithography method. At this time, in the second bump, photosensitive conductive resin paste on the first bump is irradiated with ultraviolet light from the opening of the photomask controlled based on three-dimensional CAD data while the semiconductor element is continuously moved down, and thereby a protruding portion having a necessary shape is formed (step S05). Thus, the second bump having predetermined protruding portions is formed on the first bump (step S06).

Next, the semiconductor element is taken out from the container, attached unexposed photosensitive conductive resin paste is washed, removed, and then dried. By the above-mentioned step, a conductive bump including a first bump and a second bump having protruding portions is formed on the surface of the electrode terminal of the semiconductor element (step S07).

Hereinafter, a method for forming a conductive bump in accordance with the third exemplary embodiment of the present invention is described with reference to drawings.

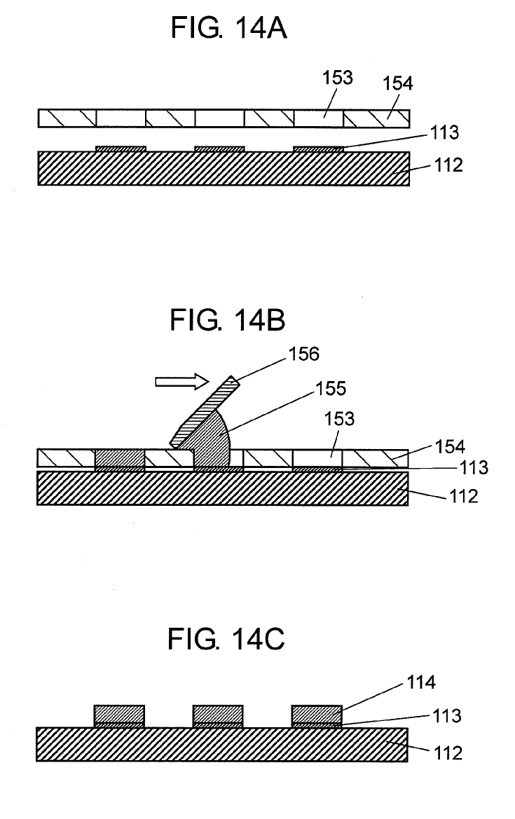

FIGS. 14A to FIG. 14C are step sectional views illustrating a method for forming a first bump of a conductive bump in accordance with the third exemplary embodiment of the present invention. As the forming method, a screen printing method is described as an example.

Firstly, as shown in FIG. 14A, above the upper surface of semiconductor element 112 provided with a plurality of electrode terminals 113, printing mask 154 having openings 153 for printing the first bump in portions corresponding to the positions of electrode terminals 113 is positioned and placed.

Next, as shown in FIG. 14B, conductive resin paste 155 including resin and conductive fillers is placed on printing mask 154, and then pressed by squeegee 156. Then, squeegee 156 is allowed to move in the direction of an arrow, thereby filling conductive resin paste 155 in opening 153 of printing mask 154.

Next, printing mask 154 is separated from semiconductor element 112, and then naturally cured or thermally cured. Thereby, as shown in FIG. 14C, first bump 114 is formed on the upper surface of electrode terminal 113. At this time, it is preferable that the printing mask is mold released. Needless to say, the printing mask may be separated after conductive resin paste 155 is cured.

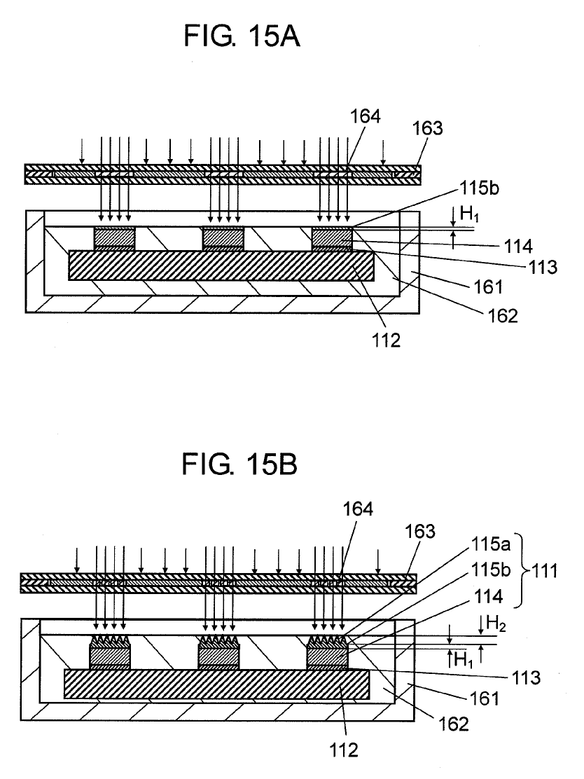

Hereinafter, a method for forming a second bump by a stereo-lithography method on the first bump formed by the above-mentioned method is described in detail with reference to FIGS. 15A and 15B.

FIGS. 15A and 15B are step sectional views illustrating a method for forming a second bump of a conductive bump in accordance with the third exemplary embodiment of the present invention.

Firstly, as shown in FIG. 15A, photocurable and photosensitive resin paste 162 containing, for example, not less than 50 wt % and less than 95 wt % of scale-shaped Sn—Ag—In alloy particles as conductive fillers in photosensitive resin (acrylate-based resin) is filled in container 161.

Then, semiconductor element 112 disposed on a stage (not shown) is immersed in photosensitive conductive resin paste 162 until the upper surface of first bump 114 formed on electrode terminal 113 of semiconductor 112 comes in a position with a predetermined interval H₁ (for example, 1 μm to 5 μm) from the liquid surface of photosensitive conductive resin paste 162.

Next, a predetermined region of photosensitive conductive resin paste 162 is irradiated with ultraviolet light or visible light and exposed to light via opening 164 of photomask 163 made of, for example, a liquid crystal panel, so that lower part 115b of the second bump is formed on first bump 114 to height H₁.

Next, as shown in FIG. 15B, irradiation with ultraviolet light or visible light is carried out via opening 164 of photomask 163, for example, while semiconductor element 112 is continuously submerged in photosensitive conductive resin paste 162 so as to continuously form a plurality of pyramid-shaped protruding portions 115a to predetermined height H₂ on the upper surface of lower surface 115b of the second bump. In this stereo-lithography method, the speed at which semiconductor element 112 is submerged and the shape of the opening of the photomask are controlled based on three-dimensional CAD data. Thereby, protruding portion 115a having a predetermined shape can be freely formed in the shapes shown in FIGS. 10, 11A and 11B. Specifically, the shape of each opening corresponding to one pyramid-shaped protruding portion can be formed by continuously reducing the size of the opening in synchronization with the speed at which the semiconductor element is submerged. Note here that the shape of the opening is reduced sequentially for each height and exposed to light, and thus pyramid-shaped protruding portions may be formed in stages.

At this time, the heights of lower part 115b and protruding portion 115a forming second bump 115 can be arbitrarily set by considering the shape of an electrode terminal of a semiconductor element, or a material and thickness of an NCF when an electronic component mounting structure is formed, or the like.

Next, on the surface of electrode terminal 113 of semiconductor element 112, conductive bump 111 is formed of first bump 114 by a printing method and second bump 115 by a stereo-lithography method. Thereafter, semiconductor element 112 is taken out from container 161 filled with photosensitive conductive resin paste 162, washed and dried.

With the above-mentioned forming method, conductive bump 111 including first bump 114 and second bump 115 having a plurality of protruding portions 115a on first bump 114 is formed on electrode terminal 113 of semiconductor element 112.

According to the forming method of this exemplary embodiment, since the first bump of the high conductive bump is formed by a printing method, as compared with the case where the entire conductive bump is formed by a stereo-lithography method, time for carrying out processes can be shortened. As a result, conductive bumps can be produced at a low cost and with high productivity.

In this exemplary embodiment, an example in which protruding portion 115a of second bump 115 has a pyramid shape is described. However, the shape is not necessarily limited to this example. For example, a trapezoid or square protruding portion can be formed by a similar method by adjusting the opening of the photomask.

Furthermore, in this exemplary embodiment, an example in which conductive bump 111 is formed on the electrode terminal of the semiconductor element is described. However, the configuration is not necessarily limited to this example. For example, conductive bump 111 may be formed on the connection terminal of a circuit board having wiring and the like by a similar forming method.

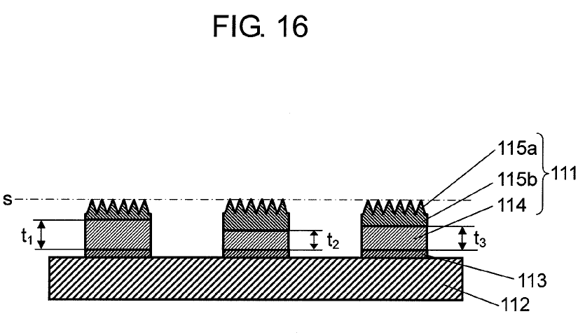

Hereinafter, the shape of the second bump formed when the thickness of the first bump formed by a printing method is different depending upon a position on semiconductor element 112 is described with reference to FIG. 16.

This is generally caused by the difference of a contraction amount of a resin component depending upon a position where the first bump is formed by printing at the time of thermal curing. Furthermore, the thickness of the first bump may be varied because warp occurs in a semiconductor element or a circuit board when the pressing force of the squeegee with respect to the printing mask is different when the first bump is formed by printing. In addition, similar phenomena may also occur when a conductive bump is formed on a circuit board with low flat accuracy having concavity and convexity due to warp and deformation.

FIG. 16 is a sectional view illustrating a structure in a case where the first bump of the conductive bump has a different thickness in accordance with the third exemplary embodiment of the present invention.

As shown in FIG. 16, since it is difficult to form the first bump having an equal thickness (height) in a printing method, a case in which the height of first bump 114 is t₁, t₂, and t₃, respectively, is described as an example. FIG. 16 is exaggerated for the purpose of easy understanding.

That is to say, when a semiconductor element having a conductive bump formed only by a printing method is mounted on other electronic component such as a circuit board, the difference in height of the conductive bump induces the following phenomenon. Firstly, when the pressurizing force at the time of mounting is low, in a portion of the conductive bump whose height is low, connection failure or connection with high connection resistance may be caused. Meanwhile, when the pressurizing force at the time of mounting is increased in order to improve the connection reliability, the pressurizing force is concentrated on the conductive bump whose height is high, which may cause cracking in a semiconductor element or destruction of a dielectric layer.

However, in the conductive bump in accordance with this exemplary embodiment, a second bump is formed by a stereo-lithography method on the upper surface of a first bump formed by a printing method. Therefore, as shown in FIG. 16, it is possible to form a conductive bump in which surface line S of the second bump can be made constant height (plane) regardless of variation of the height (thickness) of the first bump. This is because the liquid surface (corresponding to line S) of the photosensitive conductive resin paste is uniform and adjusted by the height (thickness) of the second bump. As a result, it is possible to improve the connection reliability with respect to a circuit board and the like at the time of mounting.

### Fourth Exemplary Embodiment

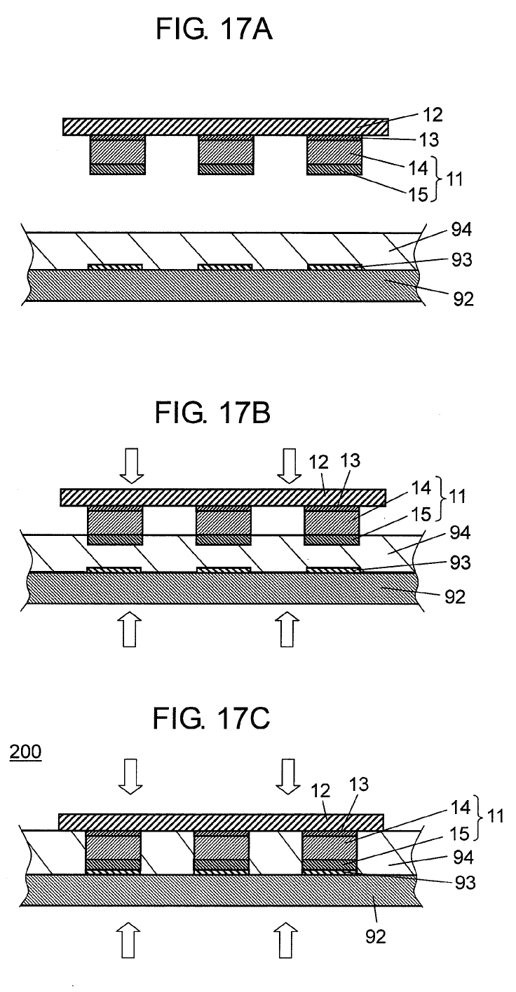

Hereinafter, an electronic component mounting structure and its manufacturing method in accordance with a fourth exemplary embodiment of the present invention are described with reference to FIGS. 17A to 17C.

FIGS. 17A to 17C are partial schematic sectional views illustrating an electronic component mounting structure and its manufacturing method in accordance with the fourth exemplary embodiment of the present invention. That is to say, electrode terminal 13 of semiconductor element 12 and connection terminal 93 of circuit board 92 are connected to each other via conductive bump 11 including first bump 14 containing spherical-shaped conductive fillers formed in the above-mentioned first exemplary embodiment and second bump 15 containing scale-shaped conductive fillers, thus forming electronic component mounting structure 200.

Firstly, as shown in FIG. 17A, semiconductor element 12 having electrode terminals 13 on which a plurality of conductive bumps 11 each including first bump 14 and second bump 15 is provided facing circuit board 92 provided with a plurality of connection terminals 93. Then, electrode terminal 13 and connection terminal 93 are positioned to each other via conductive bump 11. At this time, the upper surface of circuit board 92 is coated with resin layer 94 such as an NCF covering connection terminal 93.

Next, as shown in FIG. 17B, semiconductor element 12 having conductive bump 11 and circuit board 92 are pressed in the directions shown by arrows in the drawing and heated. Thus, semiconductor element 12 and circuit board 92 are pressed to each other via resin layer 94. At this time, they are pressed while resin layer 94 existing on connection terminal 93 of circuit board 92 is removed by protrusion bodies formed of scale-shaped conductive fillers exposed to the surface of second bump 15.

Next, as shown in FIG. 17C, at least the protruding bodies formed of scale-shaped conductive fillers exposed to the surface of at least second bump 15 of conductive bump 11 are brought into press contact with connection terminal 93 of circuit board 92 while the shape of protruding bodies is varied. Thus, connection terminal 93 of circuit board 92 is electrically coupled to electrode terminal 13 of semiconductor element 12 via conductive bump 11. Then, in a state in which they are coupled to each other, resin layer 94 existing between semiconductor element 12 and circuit board 92 is thermally cured, for example, at 120° C. for 30 minutes. Thus, semiconductor element 12 and circuit board 92 are adhesively bonded and fixed to each other.

Thus, electronic component mounting structure 200 is produced.

Note here that in electronic component mounting structure 200 having the above-mentioned configuration, for example, even when connection with respect to a semiconductor element with a low pressurizing force of 500 g weight for 100 conductive bumps is performed, a connection resistance value of not more than 20 mΩ for each conductive bump can be realized.

As mentioned above, second bump 15 whose surface is roughened with scale-shaped conductive fillers can penetrate an NCF as a resin layer with a low pressurizing force, so that electrode terminal 13 of semiconductor element 12 and connection terminal 93 of circuit board 92 can be connected to each other. As a result, since such a high pressurizing force that has been conventionally required is not needed, it is possible to realize electronic component mounting structure 200 having excellent connection reliability, in which element cracking of a semiconductor element or damage of an insulating layer including a dielectric layer with low-k can be avoided.

Furthermore, the tips of the scale-shaped conductive fillers of the second bump can be easily compressed by a press contact force at the time of connection after it penetrates the NCF. As a result, the connection area is enlarged, so that connection with respect to the connection terminal of the circuit board can be carried out with excellent electric connectivity.

According to the exemplary embodiment, since the first bump of the conductive bump is formed by containing spherical-shaped conductive fillers realizing excellent light transmittance by diffraction or reflection, the curing degree of photosensitive resin by irradiation with ultraviolet light can be enhanced. Thus, the shape maintaining ability of the conductive bump can be enhanced. Furthermore, since the second bump of the conductive bump is formed by containing scale-shaped conductive fillers having a sharpened portion, even if a resin layer such as an NCF is intervened, the second bump can penetrate the NCF with a low pressurizing force. Thus, it is possible to provide an electronic component mounting structure capable of improving connection reliability and effectively preventing an electronic component such as a semiconductor element from being damaged.

Furthermore, in this exemplary embodiment, an example in which the cross-sectional shape of the conductive bump is square is described. However, the shape is not necessarily limited to this. For example, the shapes described with reference to FIGS. 4 to 7 in the first exemplary embodiment may be employed.

Furthermore, in this exemplary embodiment, an example in which resin layer 94 such as NCF is sandwiched between semiconductor element 12 and circuit board 92 is described. However, the configuration is not necessarily limited to this. For example, the semiconductor element and the circuit board may be adhesively bonded and fixed via, for example, an anisotropic conductive resin sheet to which the scale-shaped conductive fillers of second bump 15 are allowed to cure while penetrating and pressing. With this configuration, the same effect as in the case where a resin layer is used can be obtained, and electric connectivity can be further improved with conductive particles in the anisotropic conductive resin sheet.

Furthermore, in this exemplary embodiment, an example in which a conductive bump including a first bump and a second bump is formed on an electrode terminal of a semiconductor element is described. However, a conductive bump may be formed on a connection terminal of a circuit board. In this case, the same effect can be obtained. In this case, it is preferable that a resin layer is provided on an electrode terminal of a semiconductor element. Furthermore, the conductive bump may be provided both on the electrode terminal of the semiconductor element and a connection terminal of a circuit board.

### Fifth Exemplary Embodiment

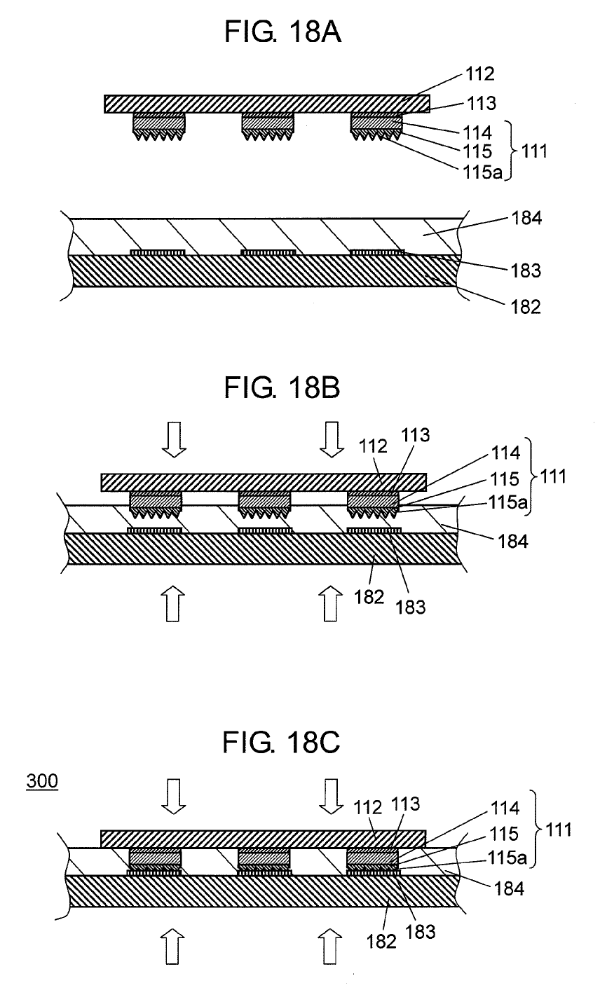

Hereinafter, an electronic component mounting structure in accordance with a fifth exemplary embodiment of the present invention are described with reference to FIGS. 18A to 18C.

FIGS. 18A to 18C are partial schematic sectional views illustrating an electronic component mounting structure in accordance with the fifth exemplary embodiment of the present invention. That is to say, electrode terminal 113 of semiconductor element 112 and connection terminal 183 of circuit board 182 are connected to each other via a plurality of conductive bumps 111 including first bump 114 formed in the above-mentioned third exemplary embodiment and second bump 115 having a plurality of pyramid-shaped protruding portions 115a, thus forming electronic component mounting structure 300.

Firstly, as shown in FIG. 18A, semiconductor element 112 having electrode terminals 113 on which a plurality of conductive bumps 111 each including first bump 114 and second bump 115 having protruding portions 115a is provided facing circuit board 182 provided with a plurality of connection terminals 183. Then, electrode terminal 113 of semiconductor element 112 and connection terminal 183 of circuit board 182 are positioned to each other via conductive bump 111. At this time, the upper surface of circuit board 182 is coated with resin layer 184 such as an NCF covering connection terminal 183.

Next, as shown in FIG. 18B, semiconductor element 112 having conductive bumps 111 and circuit board 182 are pressed in the directions shown by arrows in the drawing and heated. Thus, semiconductor element 112 and circuit board 182 are pressed to each other via resin layer 184. At this time, they are pressed while resin layer 184 on connection terminal 183 of circuit board 182 is removed by a plurality of pyramid-shaped protruding portions 115a formed at the tip of second bump 115.

Next, as shown in FIG. 18C, at least protruding portions 115a of conductive bump 111 are brought into press contact with connection terminal 183 of circuit board 182 while the shape of protruding portions 115a is deformed. Then, in a state in which they are coupled to each other, resin layer 184 existing between semiconductor element 112 and circuit board 182 is thermally cured, for example, at 120° C. for 30 minutes. Thus, semiconductor element 112 and circuit board 182 are adhesively bonded and fixed to each other.

Thus, electronic component mounting structure 300 is produced.

Note here that in electronic component mounting structure 200 having the above-mentioned configuration, for example, even when connection with respect to a semiconductor element with a low pressurizing force of 500 g weight for 100 conductive bumps is performed, a connection resistance value of not more than 20 mΩ for each conductive bump can be realized. Furthermore, as a result of a thermal-shock test at −40° C. for 30 minutes/85° C. for 30 minutes, even after 1000 cycles, the connection resistance value of not more than 20 mΩ can be achieved. Thus, excellent connection reliability can be obtained.

As mentioned above, a conductive bump having a second bump forming protrusion portions at the tip thereof can penetrate an NCF as a resin layer with a low pressurizing force. As a result, since such a high pressurizing force that has been conventionally required is not needed, it is possible to realize an electronic component mounting structure having excellent connection reliability, in which element cracking of a semiconductor element or damage of an insulating layer with low-k can be avoided.

Furthermore, after a plurality of pyramid-shaped protruding portions 115a formed on the upper surface of the second bump penetrate the NCF, they are compressed on the surface of the connection terminal by the press contact force at the time of connection and the connection area is enlarged. Thus, an excellent electrical connection property can be obtained.

According to this exemplary embodiment, the conductive bump includes a first bump formed by a printing method and a second bump formed by a stereo-lithography method, and protruding portions are provided on the upper surface of the second bump. Thereby, an electronic component mounting structure can be realized with a low pressurizing force even via a resin layer such as an NCF. Thus, connection reliability can be improved and damage in an electronic component such as a semiconductor element can be prevented effectively.

Note here that in this exemplary embodiment, an example in which the protruding portion of second bump 115 has a pyramid shape is described. The configuration is not necessarily limited to this example. For example, the protruding portion may have a columnar shape, a prismatic shape, a conical shape, a truncated cone shape, a pyramid shape, or a cylindrical shape.

Furthermore, in this exemplary embodiment, an example in which resin layer 184 such as an NCF is sandwiched between semiconductor element 112 and circuit board 182 is described. However, the configuration is not necessarily limited to this. For example, the semiconductor element and the circuit board may be adhesively bonded and fixed via an anisotropic conductive resin sheet to which protruding portions 115a of second bump 115 are allowed to cure while penetrating and pressing. Thus, the same effect as in the case where a resin layer is used can be obtained, and electric connectivity can be further improved with conductive particles in the anisotropic conductive resin sheet.

Furthermore, in this exemplary embodiment, an example in which a conductive bump including a first bump and a second bump is formed on an electrode terminal of a semiconductor element is described. However, a conductive bump may be formed on a connection terminal of a circuit board. In this case, the same effect can be obtained. In this case, it is preferable that a resin layer is provided on the electrode terminal of the semiconductor element. Furthermore, the conductive bump may be provided both on an electrode terminal of a semiconductor element and a connection terminal of a circuit board.

1. A conductive bump formed on an electrode of an electronic component, the conductive bump comprising:
a first bump having one or more layers formed on the electrode and including resin containing at least a spherical-shaped conductive filler, and
a second bump formed on an upper surface of the first bump and including photosensitive resin containing a scale-shaped conductive filler.

2. The conductive bump of claim 1, wherein the second bump is further provided between the first bump and the electrode.

3. The conductive bump of claim 1, wherein a plurality of the second bumps are provided independently on the first bump.

4. The conductive bump of claim 1, wherein the second bump has a plurality of protruding portions on at least a surface thereof.

5. The conductive bump of claim 1, wherein the first bump further contains a scale-shaped conductive filler.

6. The conductive bump of claim 1, wherein the second bump further contains a spherical-shaped conductive filler.

7. The conductive bump of claim 1, wherein one end of the scale-shaped conductive filler is exposed to an uppermost layer surface of the second bump.

8. The conductive bump of claim 1, wherein the resin is photosensitive resin or thermosetting resin.

9. The conductive bump of claim 1, wherein the electronic component is a semiconductor element or a circuit board.

10. The conductive bump of claim 1, wherein the spherical-shaped conductive filler and the scale-shaped conductive filler include at least any of one of at least one powder of metal selected from Ag, Au, Cu, and Pt, and at least one solder alloy selected from an Sn—Ag—In alloy, an Sn—Pb alloy, an Sn—Ag alloy, an Sn—Ag—Bi alloy, an Sn—Ag—Bi—Cu alloy, an Sn—Ag—In—Bi alloy, a Zn—In alloy, an Ag—Sn—Cu alloy, an Sn—Zn—Bi alloy, an In—Sn alloy, an In—Bi—Sn alloy, and an Sn—Bi alloy.

11. The conductive bump of claim 1, wherein the photosensitive resin is made of a resin material including at least one of photosensitive epoxy resin, photosensitive polyimide resin and photosensitive acrylic resin.

12. A method for forming a conductive bump formed on an electrode of an electronic component, the method comprising:
(i) forming a first bump including resin containing a spherical-shaped conductive filler; and
(ii) forming a second bump including photosensitive resin containing a scale-shaped conductive filler on the first bump,
wherein at least (ii) is carried out by using a stereo-lithography method.

13. The method for forming a conductive bump of claim 12, wherein the resin includes thermosetting resin, and (i) forms the first bump by using a printing method.

14. The method for forming a conductive bump of claim 12, wherein the resin includes photosensitive resin, and (i) forms the first bump by using a stereo-lithography.

15. The method for forming a conductive bump of claim 12, further comprising, before (i), forming a second bump including photosensitive resin containing a scale-shaped conductive filler.

16. The method for forming a conductive bump of claim 12, wherein (i) is carried out a plurality of times.

17. An electronic component mounting structure, comprising at least:
a semiconductor element having an electrode terminal;
a circuit board having a connection terminal in a position facing the electrode terminal; and
a resin layer provided between the electrode terminal of the semiconductor element and the connection terminal of the circuit board,
wherein the semiconductor element and the circuit board are connected to each other via the conductive bump of claim 1 provided on at least one of the electrode terminal and the connection terminal.

18. The conductive bump of claim 8, wherein the photosensitive resin is made of a resin material including at least one of photosensitive epoxy resin, photosensitive polyimide resin and photosensitive acrylic resin.
